(19) United States
(12) Patent Application Publication
(10) Pub. No.: US 2010/0055888 A1
(43) Pub. Date: Mar. 4, 2010

(54) Semiconductor device fabrication method

(75) Inventor: Atsushi Yabata, Miyagi (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/461,984

(22) Filed: Aug. 31, 2009

(30) Foreign Application Priority Data
Sep. 1, 2008 (JP) 2008-223806

(51) Int. Cl. H01L 21/28

(52) U.S. Cl. 438/585; 257/E21.214; 257/E21.158

(57) ABSTRACT

There is provided a semiconductor device fabrication method including: forming a gate electrode film on a substrate; forming an antireflection film on a surface at the opposite side of the gate electrode film to the substrate; forming a resist pattern on a surface at the opposite side of the antireflection film to the gate electrode film; irradiating plasma on the resist pattern by using an etching apparatus having an electrode for pulling-in ions within the plasma, by applying bias power to the electrode for pulling-in ions within the plasma such that an etching rate at the resist pattern becomes less than or equal to 100 Å/min to generate the plasma by using a gas that is non-reactive with the resist pattern; etching the antireflection film and the gate electrode by using, as a mask, the resist pattern; and removing the resist pattern and the antireflection film.

### CROSS-REFERENCE TO RELATED APPLICATION

This application is based on and claims priority under 35 USC 119 from Japanese Patent Application No. 2008-223806 filed on Sep. 1, 2008, the disclosure of which is incorporated by reference herein.

### BACKGROUND

1. Technical Field

The present invention relates to a semiconductor device fabricating method, and in particular, to a semiconductor device fabricating method in which line edge roughness (hereinafter abbreviated as “LER” upon occasion) of a resist pattern is reduced.

2. Related Art

Semiconductor nonvolatile memories are currently utilized as memories of low-power equipment such as cell phones and the like because electric power is not needed in order to maintain stored information.

As one such semiconductor device, there is proposed an FD (Full Depletion) MOS (Metal-Oxide Semiconductor) FET (Field Effect Transistor) semiconductor device that is formed on an SOI (Silicon On Insulator) substrate. In this semiconductor device, a depression is formed in the surface of the semiconductor substrate, and a portion of a gate electrode is filled in the depression.

Here, in the forming of gate electrodes of MOS transistors, dimensional conversion differences and dimensional dispersion, that are due to the gate electrodes being etched, are major factors that determine the transistor characteristics.

In conventional techniques, there is generally a method in which the shape of the resist pattern that is a mask at the time of etching the gate electrodes is controlled by changing the conditions of the etching gas of the antireflection film, and due thereto, the aforementioned dimensional conversion differences are controlled. If the dimensions of the gate electrodes are made to be narrow, the resist is retracted by using oxygen or fluorocarbon gas or the like, that has high reactivity with the resist, as the etching gas of the antireflection film, and etching of the gate electrodes is carried out by using the resist pattern that is formed in this way as a mask. Conversely, if the dimensions of the gate electrodes are made to be wide, the deposition film at the side wall of the resist pattern is deposited and made to be wide by using C₁₂ gas or the like, and etching of the gate electrodes is carried out by using the resist pattern that is formed in this way as a mask. Namely, the characteristics of the dimensional conversion differences vary greatly in accordance with the etching gas of the antireflection film, and the selection of the type of gas is important.

On the other hand, with regard to the aforementioned dimensional dispersion, if LER (line edge roughness) arises at the resist pattern, this LER is transferred at the time of etching the gate electrodes, and, as a result, dimensional dispersion arises at the gate electrodes. Accordingly, at the time of etching the gate electrodes, it is desired to reduce the occurrence of LER at the resist pattern.

Here, among semiconductor device fabricating methods that include a dry etching step using a DUV resist pattern, there is disclosed a semiconductor device fabricating method that has, as the object thereof, avoiding faceting of the resist pattern and simultaneously avoiding pattern density dependence of the obtained pattern width. Specifically, there is a semiconductor device fabricating method that, before the dry etching step, exposes the resist pattern to plasma that uses a non-depositing gas and forms a hardened layer on the resist surface (see, for example, Japanese Patent Application Laid-Open (JP-A) No. 2000-91318). However, in accordance with this fabricating method as well, the occurrence of LER at the resist pattern cannot be suppressed, and the problem of dimensional dispersion of the gate electrodes is not solved.

Conventionally, when making the dimensions of gate electrodes narrow by using an anisotropic etching apparatus, a method is used that retracts (makes narrow) the resist pattern by using a gas having high chemical reactivity with the resist as the gas that is used at the time of etching the antireflection film. Accordingly, the isotropy of the etching characteristic becomes strong, differences in local etching amounts arise in the side wall direction of the resist pattern, and, as a result, there is the problem of LER (line edge roughness) arising at the resist pattern.

### SUMMARY

An object of the present invention is to provide a semiconductor device fabricating method that suppresses the occurrence of dimensional dispersion at gate electrodes and can form gate electrodes having narrow dimensions, and a semiconductor device in which the dimensions of gate electrodes are narrow and the occurrence of dimensional dispersion at the gate electrodes is suppressed.

As the result of earnest studies, the present inventors found that the above-described problems could be solved by using the following semiconductor device fabricating method, and achieved the above-described object.

Namely, an aspect of the present invention provides a semiconductor device fabrication method including:

a) forming a gate electrode film on one surface side of a substrate;

b) forming an antireflection film on a surface at the opposite side of the gate electrode film to the substrate;

c) forming a resist pattern on a surface at the opposite side of the antireflection film to the gate electrode film;

d) irradiating plasma on the resist pattern by using an etching apparatus having an electrode for pulling-in ions that are within the plasma, by applying bias power to the electrode for pulling-in ions that are within the plasma such that an etching rate at the resist pattern becomes less than or equal to 100 Å/min to generate the plasma by using a gas that is non-reactive with the resist pattern;

e) etching the antireflection film and the gate electrode by using, as a mask, the resist pattern that has undergone d) the irradiating of plasma; and

f) removing the resist pattern and the antireflection film that have undergone e) the etching.

Conventionally, when making the dimensions of the gate electrodes narrow by using an anisotropic etching apparatus, a method is used that retracts (makes narrow) the resist pattern by using a gas having high chemical reactivity with the resist as the gas used at the time of etching the antireflection film. Accordingly, the isotropy of the etching characteristic becomes strong, differences in local etching amounts arise in the side wall direction of the resist pattern, and, as a result, there is the problem of LER (line edge roughness) arising at the resist pattern.

Further, also in the semiconductor device fabricating method disclosed in aforementioned JP-A No. 2000-91318, the resist pattern is etched because ions are perpendicularly incident on the resist pattern from the plasma. As a result, there are the problems that differences in local etching amounts arise in the side wall direction of the resist pattern, and LER arises at the resist pattern.

In the semiconductor device fabricating method of the first aspect of the present invention, as described above, at an electrode for pulling-in ions that are within plasma, bias power is applied such that the etching rate at the resist pattern becomes less than or equal to 100 Å/min. Namely, this is a condition that the bias power at the electrode for pulling-in ions that are within plasma is applied extremely low, or is not applied. It is surmised that, due to bias power being applied low or not being applied as described above, the amount of ions that are perpendicularly incident on the resist pattern from the plasma is suppressed, and as a result, it is surmised that the etching rate at the resist pattern is kept to less than or equal to 100 Å/min. By keeping the etching rate of the resist pattern to less than or equal to 100 Å/min, LER (line edge roughness) does not arise at the resist pattern, and as a result, the occurrence of dimensional dispersion at the gate electrodes is effectively suppressed.

Moreover, due to the amount of ions that are perpendicularly incident on the resist pattern from the plasma being suppressed as described above, film reduction due to sputtering at the resist pattern is effectively reduced.

Further, because charge-up of the resist pattern also is suppressed, the occurrence of abnormalities in shape due to the electron shading effect is effectively prevented even when etching the antireflection film and the gate electrodes by using, as a mask, a resist pattern that has undergone the plasma irradiating step.

In the semiconductor device fabricating method of the first aspect of the present invention, as described above, the amount of ions that are perpendicularly incident on the resist pattern from the plasma is suppressed and etching of the resist pattern is suppressed, and further, ultraviolet light that is contained within the plasma is irradiated on the resist pattern. A resist pattern onto which ultraviolet light is irradiated shrinks and becomes narrow. Namely, a resist pattern that is formed by the above-described method does not become narrow by being removed as by etching, and can effectively be made to be narrow without being accompanied by the occurrence of LER due to shrinkage. As a result, gate electrodes having narrow dimensions can be fabricated effectively.

According to a second aspect of the present invention, the bias power that is applied to the electrode for pulling-in ions that is within the plasma may be from 0 W to 40 W.

In a semiconductor device fabricating method of the second aspect of the present invention, by keeping the bias power that is applied to the electrode for pulling-in ions that are within plasma to greater than or equal to 0 W and less than or equal to 40 W, the etching rate at the resist pattern can be adjusted so as to become less than or equal to 100 Å/min. Due thereto, as described above, it is surmised that the amount of ions that are perpendicularly incident on the resist pattern from the plasma is suppressed. As a result, LER (line edge roughness) does not occur at the resist pattern, and the occurrence of dimensional dispersion at the gate electrodes is effectively suppressed. Further, film reduction due to sputtering at the resist pattern is effectively reduced.

According to a third aspect of the present invention, ultraviolet light, that has a wavelength to which the resist pattern is photosensitive, may be included within the plasma.

In a semiconductor device fabricating method of the third aspect of the present invention, due to ultraviolet light that is contained in the plasma having a wavelength that is photosensitive with the resist pattern, the resist pattern on which the ultraviolet light is irradiated can be effectively shrunk and made to be narrow. Namely, the resist pattern formed by the above-described method does not become narrow by being removed as by etching, and can more effectively be made to be narrow without being accompanied by the occurrence of LER due to shrinkage. As a result, gate electrodes having narrow dimensions can be fabricated effectively.

According to a fourth aspect of the present invention, the resist pattern may be formed by using at least one selected from a KrF resist or an ArF resist.

A fifth aspect of the present invention provides a semiconductor device fabricated by the above semiconductor device fabrication method of the first to fourth aspects.

In accordance with a semiconductor device of the fifth aspect of the present invention, there is provided a semiconductor device in which the dimensions of gate electrodes are narrow and the occurrence of dimensional dispersion at the gate electrodes is suppressed.

In accordance with the present invention, there are provided a semiconductor device fabricating method that suppresses the occurrence of dimensional dispersion at gate electrodes and can form gate electrodes having narrow dimensions, and a semiconductor device in which the dimensions of gate electrodes are narrow and the occurrence of dimensional dispersion at the gate electrodes is suppressed.

### BRIEF DESCRIPTION OF THE DRAWINGS

An exemplary embodiment of the present invention will be described in detail based on the following figures, wherein:

FIG. 1 is a cross-sectional view of a conventional semiconductor device;

FIG. 2 is a cross-sectional view showing a state in which a gate electrode film is formed on one surface side of a substrate in a semiconductor device fabricating method of an exemplary embodiment of the present invention;

FIG. 3 is a cross-sectional view showing a state in which an antireflection film is formed in the semiconductor device fabricating method of the exemplary embodiment of the present invention;

FIG. 4 is a cross-sectional view showing a state in which a resist pattern is formed and plasma is irradiated in the semiconductor device fabricating method of the exemplary embodiment of the present invention;

FIG. 5 is a cross-sectional view showing a state in which the antireflection film and a gate electrode are etched in the semiconductor device fabricating method of the exemplary embodiment of the present invention;

FIG. 6 is a cross-sectional view showing a state in which the resist pattern and the antireflection film are removed in the semiconductor device fabricating method of the exemplary embodiment of the present invention;

FIG. 7 is a graph showing experimental results of He plasma discharge time dependence with respect to dimension (150 nm in an initial period) of the resist pattern;

FIG. 8 is a graph showing experimental results of He plasma discharge time dependence of the degree of occurrence of LER of the resist pattern; and

FIG. 9 is a schematic structural drawing showing an inductive coupled plasma etcher.

### DETAILED DESCRIPTION

### <Semiconductor Device Fabricating Method>

A preferred embodiment for implementing the semiconductor device fabricating method of the present invention will be described in detail hereinafter.

The semiconductor device fabricating method relating to the present exemplary embodiment includes:
(1) a gate electrode film forming step that forms at least a gate electrode film on one surface side of a substrate;
(2) an antireflection film forming step that forms an antireflection film on a surface of the gate electrode film at a side opposite the substrate;
(3) a resist pattern forming step that forms a resist pattern on a surface of the antireflection film at a side opposite the gate electrode film;
(4) a plasma irradiating step that, by using an etching apparatus having an electrode for pulling-in ions that are within plasma, applies bias power to the electrode for pulling-in ions that are within plasma such that an etching rate at the resist pattern becomes less than or equal to 100 Å/min, and generates plasma by using a gas that is non-reactive with the resist pattern, and irradiates the plasma on the resist pattern;
(5) an etching step that etches the antireflection film and the gate electrode by using, as a mask, the resist pattern that has undergone the plasma irradiating step; and
(6) a resist pattern and antireflection film removing step that removes the resist pattern and the antireflection film that have undergone the etching step.

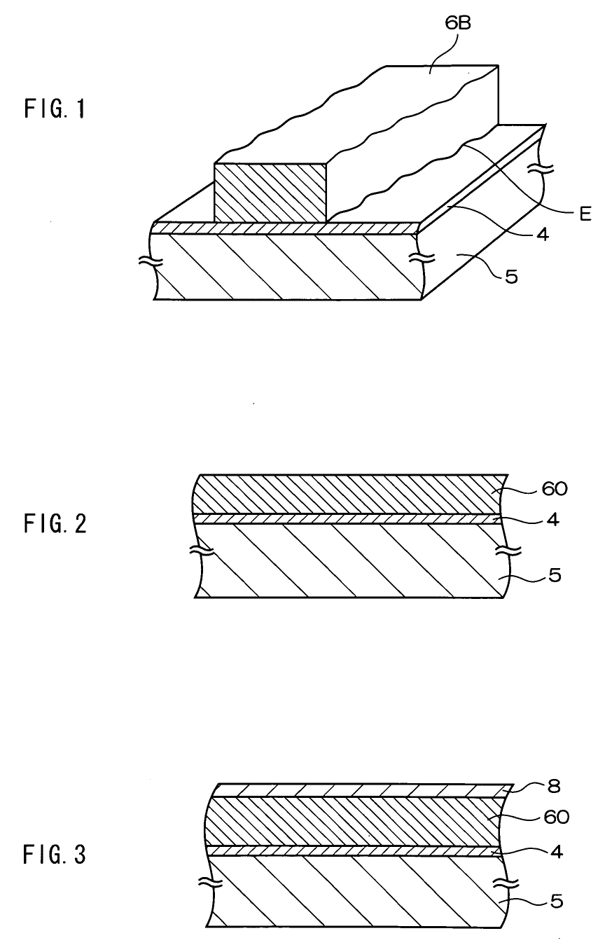

As shown in FIG. 1, in a conventional semiconductor device fabricating method, when a gate electrode 6B is formed on the surface of a substrate 5 having a gate insulating film 4, the occurrence of LER (line edge roughness) at the resist pattern that is used as a mask at the time of etching the gate electrode is problematic. Therefore, there is the problem that dimensional dispersion arises at edge E portions at the gate electrode 6B.

In contrast, in the semiconductor device fabricating method relating to the present exemplary embodiment, as described above, at an electrode for pulling-in ions that are within plasma, bias power is applied so that the etching rate at the resist pattern becomes less than or equal to 100 Å/min. It is surmised that, due thereto, the amount of ions that are perpendicularly incident from the plasma onto the resist pattern are suppressed, and, as a result, LER (line edge roughness) does not arise at the resist pattern, and the occurrence of dimensional dispersion at the gate electrodes is effectively suppressed.

Further, due to the amount of ions that are perpendicularly incident on the resist pattern from the plasma being suppressed as described above, film reduction due to sputtering at the resist pattern is effectively reduced.

Moreover, because charge-up of the resist pattern also is suppressed, the occurrence of abnormalities in shape due to the electron shading effect is effectively prevented even when etching the antireflection film and the gate electrode by using, as a mask, the resist pattern that has undergone the plasma irradiating step.

In the semiconductor device fabricating method relating to the present exemplary embodiment, as described above, the amount of ions that are perpendicularly incident on the resist pattern from the plasma is suppressed and etching of the resist pattern is suppressed, and further, the ultraviolet light that is contained within the plasma is irradiated on the resist pattern. A resist pattern onto which ultraviolet light is irradiated shrinks and becomes narrow. Namely, a resist pattern that is formed by the above-described method does not become narrow by being removed as by etching, and can effectively be made to be narrow without being accompanied by the occurrence of LER due to shrinkage. As a result, gate electrodes having narrow dimensions can be fabricated effectively.

Note that, at the electrode for pulling-in ions that are within plasma, when bias power that is such that the etching rate at the resist pattern exceeds 100 Å/min is applied, LER (line edge roughness) arises at the resist pattern, and dimensional dispersion at the gate electrodes arises. Further, at the resist pattern, film reduction due to sputtering markedly arises.

It is further preferable that the bias power, that is applied to the electrode for pulling-in ions that are within plasma, is adjusted such that the etching rate at the resist pattern becomes less than or equal to 95 Å/min, and particularly preferable that it is adjusted such that the etching rate becomes less than or equal to 85 Å/min.

Here, from the standpoint of adjusting the bias power such that the etching rate at the resist pattern becomes less than or equal to 100 Å/min, it is preferable that the bias power applied to the electrode for pulling-in ions within plasma be adjusted to be greater than or equal to 0 W and less than or equal to 40 W, and it is more preferable that the bias power be adjusted to be greater than or equal to 0 W and less than or equal to 35 W, and it is particularly preferable that the bias power be adjusted to be greater than or equal to 0 W and less than or equal to 30 W.

From the standpoint of more effectively shrinking and making narrow the resist pattern at which ultraviolet light is irradiated, it is preferable that the ultraviolet light contained within the plasma have a wavelength that is photosensitive with the resist pattern.

Next, the semiconductor device fabricating method relating to the present exemplary embodiment will be described in accordance with the drawings. Note that redundant explanation may be omitted.

### (1) Gate Electrode Film Forming Step

In the semiconductor device fabricating method relating to the present exemplary embodiment, first, as shown in FIG. 2, at least a gate electrode film (a film that is formed from a material for forming gate electrodes) 60 is formed on one surface side of the substrate 5. Note that the gate electrode film 60 may be formed with a gate insulating film 4 between the gate electrode film 60 and the substrate 5.

For example, an SOI substrate (a substrate of a structure in which SiO₂ is inserted between an Si substrate and a surface Si layer), an Si substrate, or the like can be used as the substrate 5.

SiO₂, SiON, and the like are examples of the material forming the gate insulating film 4.

Note that the formation of the gate insulating film 4 can be carried out by a conventionally known method. For example, the gate insulating film 4 can be formed by a method such as dry oxidation that oxidizes only by O₂, wet oxidation that causes H₂ and O₂ to react at a high temperature and oxidizes by H₂O, or the like.

Examples of the material that forms the gate electrode film (the film that is formed from a material for forming the gate electrodes) 60 are poly-Si, P dope poly-Si, WSix-Polycide, and the like.

Note that the formation of the gate electrode film 60 can be carried out by a conventionally known method. For example, the gate electrode film 60 can be formed by a method such as CVD or the like.

### (2) Antireflection Film Forming Step

Next, in the semiconductor device fabricating method relating to the present exemplary embodiment, as shown in FIG. 3, an antireflection film 8 is formed on the surface of the gate electrode film 60 at the side opposite the substrate 5.

Examples of the material that forms the antireflection film 8 are organic antireflection films, SiON, TiN, and the like.

Note that the formation of the antireflection film can be carried out by a conventionally known method. For example, if an organic antireflection film is used, the antireflection film 8 can be formed by spin coating or the like. If SiON is used, the antireflection film 8 can be formed by CVD or the like. If TiN is used, the antireflection film 8 can be formed by sputtering, CVD or the like.

### (3) Resist Pattern Forming Step

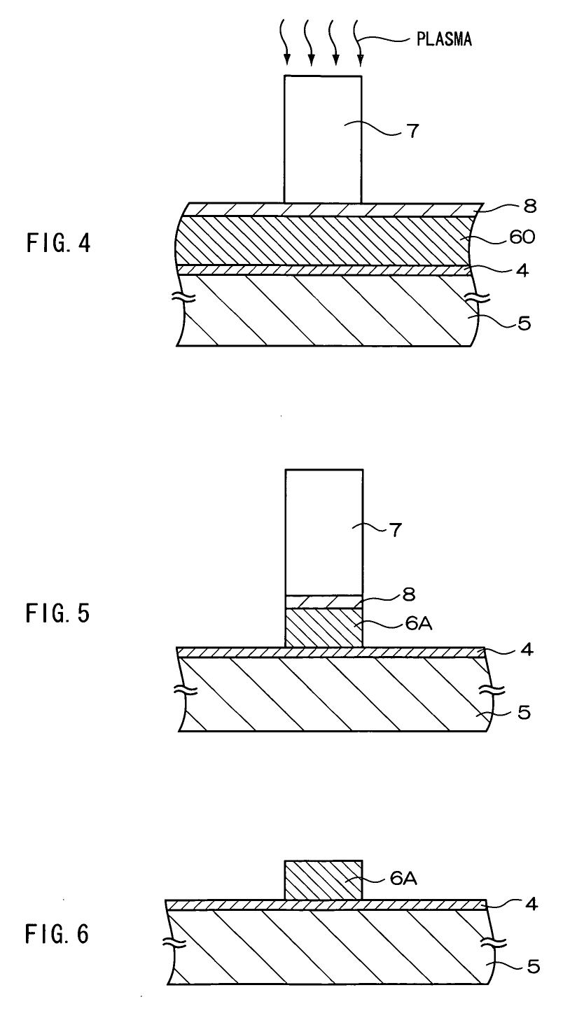

Next, in the semiconductor device fabricating method relating to the present exemplary embodiment, as shown in FIG. 4, a resist pattern is formed on the surface of the antireflection film 8 at the side opposite the gate electrode film 60. More specifically, first, a film (resist film) that is formed of a material for forming the resist pattern 7 is formed on the entire surface of the antireflection film 8, and then, the resist pattern 7 is formed by patterning the resist film.

Examples of materials that form the resist film are a KrF resist, an ArF resist, and the like.

Note that formation of the resist film can be carried out by a conventionally known method. For example, the resist film can be formed by methods such as a spin coating method, a method that carries out baking for volatilizing a resist solvent after spin coating, or the like.

Further, the patterning of the resist film can be carried out by a conventionally known method such as a lithographic technique or the like. For example, the patterning can be carried out by a method that photosensitizes the resist by exposure and dissolves and removes the photosensitized resist by developing, or the like.

### (4) Plasma Irradiating Step

Next, in the semiconductor device fabricating method relating to the present exemplary embodiment, as shown in FIG. 4, by using an etching apparatus having an electrode for pulling-in ions that are within plasma, bias power is applied to the electrode for pulling-in ions that are within plasma such that the etching rate at the resist pattern 7 becomes less than or equal to 100 Å/min, and plasma is generated by using a gas that is non-reactive with the resist pattern 7 and is irradiated on the resist pattern 7.

Note that measurement of the etching rate can be carried out by the following method.

By using an AFM atomic force microscope, a probe is made to contact the resist pattern 7 on which plasma irradiation has been carried out, and the amount of change (film reduction amount) from the resist pattern 7 before the plasma irradiation is measured. A value, in which the amount of change of the resist pattern 7 is converted by 60 seconds of plasma irradiation time, is the etching rate.

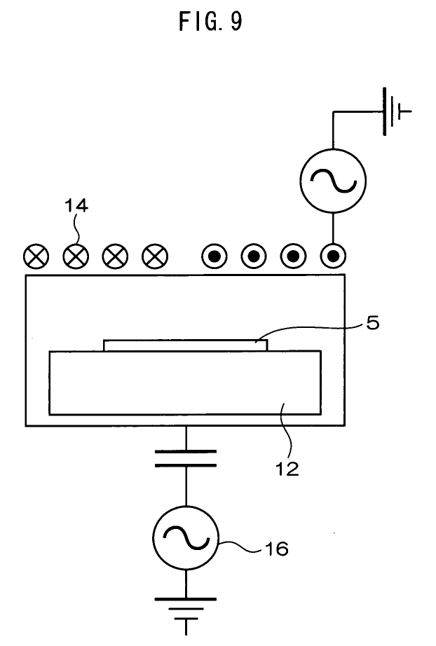

Here, an inductive coupled plasma etcher is illustrated in FIG. 9 as a concrete example of an etching apparatus having an electrode for pulling-in ions that are within plasma.

The inductive coupled plasma etcher shown in FIG. 9 has a lower electrode 12 that is an electrode for pulling-in ions that are within plasma, and has a wafer stage 50 on the lower electrode 12. In the inductive coupled plasma etcher shown in FIG. 9, a body to be irradiated that is plasma-irradiated (i.e., in the semiconductor device fabricating method relating to the present exemplary embodiment, the substrate 5 that has undergone the resist pattern forming step) is set at the wafer stage 50, and plasma irradiation is carried out. Note that the bias power that is applied to the lower electrode 12 from an RF bias generator 16 is adjusted such that the etching rate at the resist pattern 7 becomes less than or equal to 100 Å/min, and plasma is discharged by applying high frequency electric power to antennas 14. More specifically, as described above, it is preferable that the bias power that is applied to the lower electrode 12 be greater than or equal to 0 W and less than or equal to 40 W.

Further, at the above-described inductive coupled plasma etcher, the chemical reaction with the resist is suppressed by using a gas that is non-reactive with the resist pattern 7, and the plasma is generated. Examples of gases that are non-reactive with the resist pattern 7 are rare gases, N₂ gas and the like, and these are particularly effective when at least one type selected from the aforementioned KrF resist and ArF resist is used as the resist pattern 7.

### (5) Etching Step

Next, in the semiconductor device fabricating method relating to the present exemplary embodiment, as shown in FIG. 5, the antireflection film 8 and the gate electrode film 60 are etched by using, as a mask, the resist pattern 7 that has undergone the plasma irradiation step.

The etching of the antireflection film 8 and the gate electrode film 60 can be carried out by a conventionally known method. For example, the etching can be carried out by a method that causes ions and radicals within the plasma to be incident on the antireflection film 8 and the gate electrode film 60 and advances the etching by the chemical reaction between the radicals and the sputtering by the ions, or the like.

### (6) Resist Pattern and Antireflection Film Removing Step

Next, in the semiconductor device fabricating method relating to the present exemplary embodiment, as shown in FIG. 6, the resist pattern 7 and the antireflection film 8 that have undergone the above-described etching step are removed.

The removal of the resist pattern 7 and the antireflection film 8 can be carried out by a conventionally known method. For example, the removal can be carried out by a method such as ashing in which ozone or oxygen that has been thermally decomposed or made into plasma is irradiated onto the resist pattern 7 and the antireflection film 8 and the resist is removed by the chemical reaction, or the like.

The semiconductor device fabricating method relating to the present exemplary embodiment is carried out has described above.

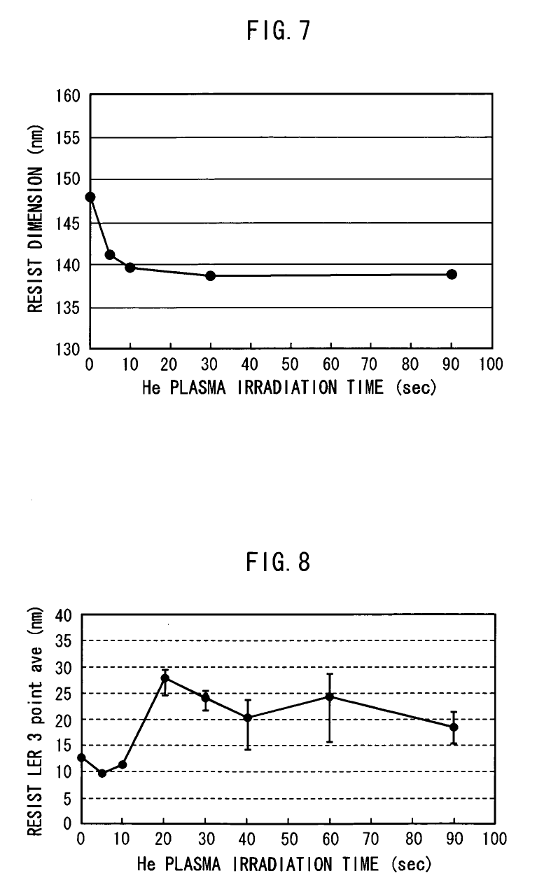

Experimental examples of “He plasma discharge time dependence with respect to dimension (150 nm in an initial period) of the resist pattern” are shown in FIG. 7, and experimental examples of “He plasma discharge time dependence of the degree of occurrence of LER of the resist pattern” are shown in FIG. 8. Note that the plasma irradiating conditions are as follows.

### (Plasma Irradiating Conditions)

apparatus: inductive coupled plasma etcher (ALLIANCE 9400DFM, manufactured by LAM Research)

pressure: 10 mT, TCP power: 300 W

lower electrode bias power: 0 W

gas: He gas, gas flow rate: 100 sccm

lower electrode temperature: 60° C.

In FIG. 7, it can be understood that the dimension of the resist pattern becomes narrower by approximately 10% until a discharge time of 10 seconds, and is saturated thereafter. On the other hand, in FIG. 8, it can be understood that the occurrence of LER of the resist pattern decreases approximately 25% at the point in time of a discharge time of 10 seconds, and increases thereafter. It is surmised that this arises due to the resist pattern being photosensitized by ultraviolet light within the plasma. Accordingly, in the semiconductor device fabricating method relating to the present exemplary embodiment, the irradiation time of the plasma in the (4) plasma irradiating step is preferably made to be greater than or equal to 1 second and less than or equal to 10 seconds.

### EXAMPLES

The above semiconductor device fabricating method relating to the present exemplary embodiment will be further described by using Examples.

### Example 1

By using the above-described semiconductor device fabricating method relating to the present exemplary embodiment, a resist pattern was formed by using a KrF resist, and plasma irradiation was carried out under the following irradiation condition using a gas that was non-reactive with the resist pattern.

### (Plasma Irradiating Conditions)

apparatus: inductive coupled plasma etcher (ALLIANCE 9400DFM, manufactured by LAM Research)

pressure: 10 mT, TCP power: 300 W

lower electrode bias power: 0 W

gas: He gas, gas flow rate: 100 sccm

lower electrode temperature: 60° C.

irradiation time: 90 seconds

As described above, it is preferable that the plasma irradiation time be less than or equal to 10 seconds. However, in the present Example, irradiation of 90 seconds was carried out as a stress condition. The same holds for the following Examples and Comparative Examples.

Note that the etching rate was 81 Å/min.

Evaluations on the resist pattern after the plasma irradiation were carried out in accordance with the following methods.

### [Evaluation Methods]

### —Film Reduction Amount of Resist Pattern—

By using an AFM atomic force microscope, a probe was made to contact the resist pattern, and the amount of change (film reduction amount) from the resist pattern (4000 Å) before the plasma irradiation was measured. The results are shown in Table 1.

Note that a value, in which the film reduction amount of the resist pattern 7 is converted by 60 seconds of plasma irradiation time, is the etching rate.

### —Surface Roughness of Resist Pattern—

By using an AFM atomic force microscope, a probe was made to contact the resist pattern, and the surface roughness (Ra/Roughness Average) was measured. Note that measurement of a range of a surface area of 300 nm×300 nm was carried out per interval of 1 nm, and the average value thereof was determined. The results are shown in Table 1.

### Comparative Example 1

A resist pattern formed in the same way as in Example 1 was subjected to plasma irradiation under the following irradiating conditions using a reactive gas.

### (Plasma Irradiating Conditions)

apparatus: inductive coupled plasma etcher (ALLIANCE 9400DFM, manufactured by LAM Research)

pressure: 10 mT, TCP power: 300 W

lower electrode bias power: 0 W

gas: HBr gas, gas flow rate: 100 sccm

lower electrode temperature: 60° C.

irradiation time: 90 seconds

Note that the etching rate was 153 Å/min.

The resist pattern after the plasma irradiation was evaluated by the same methods as in Example 1. The results are shown in Table 1.

### Comparative Example 2

A resist pattern formed in the same way as in Example 1 was subjected to plasma irradiation under the following irradiating conditions using a non-reactive gas.

### (Plasma Irradiating Conditions)

apparatus: inductive coupled plasma etcher (ALLIANCE 9400DFM, manufactured by LAM Research)

pressure: 10 mT, TCP power: 300 W

lower electrode bias power: 100 W

gas: He gas, gas flow rate: 100 sccm

lower electrode temperature: 60° C.

irradiation time: 90 seconds

Note that the etching rate was 250 Å/min.

The resist pattern after the plasma irradiation was evaluated by the same methods as in Example 1. The results are shown in Table 1.

### Example 2

A resist pattern formed in the same way as in Example 1 was subjected to plasma irradiation under the following irradiating conditions using a non-reactive gas.

### (Plasma Irradiating Conditions)

apparatus: inductive coupled plasma etcher (ALLIANCE 9400DFM, manufactured by LAM Research)

pressure: 10 mT, TCP power: 300 W

lower electrode bias power: 40 W

gas: He gas, gas flow rate: 100 sccm

lower electrode temperature: 60° C.

irradiation time: 90 seconds

Note that the etching rate was 93 Å/min.

The resist pattern after the plasma irradiation was evaluated by the same methods as in Example 1. The results are shown in Table 1.

### Comparative Example 3

A resist pattern formed in the same way as in Example 1 was subjected to plasma irradiation under the following irradiating conditions using a non-reactive gas.

### (Plasma Irradiating Conditions)

apparatus: inductive coupled plasma etcher (ALLIANCE 9400DFM, manufactured by LAM Research)

pressure: 10 mT, TCP power: 300 W

lower electrode bias power: 55 W

gas: He gas, gas flow rate: 100 sccm

lower electrode temperature: 60° C.

irradiation time: 90 seconds

Note that the etching rate was 126 Å/min.

The resist pattern after the plasma irradiation was evaluated by the same methods as in Example 1. The results are shown in Table 1.

TABLE 1

| | | Comp. | Comp. | | Comp. |
|---|---|---|---|---|---|
| | Example 1 | Example 1 | Example 2 | Example 2 | Example 3 |
| lower | 0 W | 0 W | 100 W | 40 W | 55 W |
| electrode | | | | | |
| bias power | | | | | |
| [W] | | | | | |
| gas | He | HBr | He | He | He |
| etching rate | 81 | 153 | 250 | 93 | 126 |
| [Å/min] | | | | | |
| film | 121 | 229 | 375 | 139 | 189 |
| reduction | | | | | |
| amount [Å] | | | | | |
| surface | 2.7 | 30.5 | 4.2 | 3.5 | 4.0 |
| roughness | | | | | |
| [nm] | | | | | |

What is claimed is:

1. A semiconductor device fabrication method comprising:
a) forming a gate electrode film on one surface side of a substrate;
b) forming an antireflection film on a surface at the opposite side of the gate electrode film to the substrate;
c) forming a resist pattern on a surface at the opposite side of the antireflection film to the gate electrode film;
d) irradiating plasma on the resist pattern by using an etching apparatus having an electrode for pulling-in ions that are within the plasma, by applying bias power to the electrode for pulling-in ions that are within the plasma such that an etching rate at the resist pattern becomes less than or equal to 100 Å/min to generate the plasma by using a gas that is non-reactive with the resist pattern;
e) etching the antireflection film and the gate electrode by using, as a mask, the resist pattern that has undergone d) the irradiating of plasma; and
f) removing the resist pattern and the antireflection film that have undergone e) the etching.

2. The semiconductor device fabrication method of claim 1, wherein the bias power that is applied to the electrode for pulling-in ions that are within the plasma is from 0 W to 40 W.

3. The semiconductor device fabrication method of claim 1, wherein ultraviolet light, that has a wavelength to which the resist pattern is photosensitive, is included within the plasma.

4. The semiconductor device fabrication method of claim 1, wherein the resist pattern is formed by using at least one selected from a KrF resist or an ArF resist.
